(19) United States
(12) Patent Application Publication
(10) Pub. No.: US 2009/0321935 A1
(43) Pub. Date: Dec. 31, 2009

(54) Methods of forming improved electromigration resistant copper films and structures formed thereby

(76) Inventors: Kevin O'Brien, Portland, OR (US); Florian Gstrein, Portland, OR (US); Sridhar Balakrishnan, Portland, OR (US)

Correspondence Address: INTEL CORPORATION;c/o CPA Global, P.O. BOX 52050, MINNEAPOLIS, MN, 55402, US

(21) Appl. No.: 12/215,987

(22) Filed: Jun. 30, 2008

(51) Int. Cl. H01L 21/768; H01L 23/532

(52) U.S. Cl. 257/751; 438/643; 257/E21.584; 257/E23.155

(57) ABSTRACT

Methods and associated structures of forming a microelectronic structure are described. Those methods may comprise forming a doping material on an overburden region of a conductive structure, diffusing a portion of the doping material into a portion of the conductive structure, and then removing the overburden region.

### BACKGROUND OF THE INVENTION

As is well known to those in the art, conductive interconnects may suffer from an electromigration problem, that is as interconnect dimensions shrink on devices there is a natural increase in the current density found in interconnects. The higher the current density, the more susceptible interconnects are to electromigration. During the fabrication of microelectronic devices, a conductive alloyed seed layer may be formed in an interconnect structure opening, such as a Damascene opening, for example. The seed may be formed prior to bulk formation of a conductive material, such as copper, that may be used to form conductive interconnect structures. The enablement of high current densities are desirable in the design of such conductive interconnect structures, which improves the electromigration resistance of the interconnect structures.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1k represent cross-sections of structures that may be formed when carrying out an embodiment of the methods of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure, such as a copper interconnect structure, are described. Those methods may comprise forming a doping material that may dope an overburden region of a conductive structure, diffusing a portion of the doping material into a portion of the conductive structure, and then removing the overburden region from the conductive structure. Doping the overburden region may also be combined with more traditional measures of doping from a seed layer or from doping from a barrier itself, in some cases, thus allowing for the tuning of the doping percentage and the location of the dopant within an interconnect material. The various embodiments of the present invention enable the alloying of conductive interconnects using overburden doping from the top of the conductive structure, facilitating the fabrication of sub 100 nm conductive interconnects that are not limited by electromigration failures.

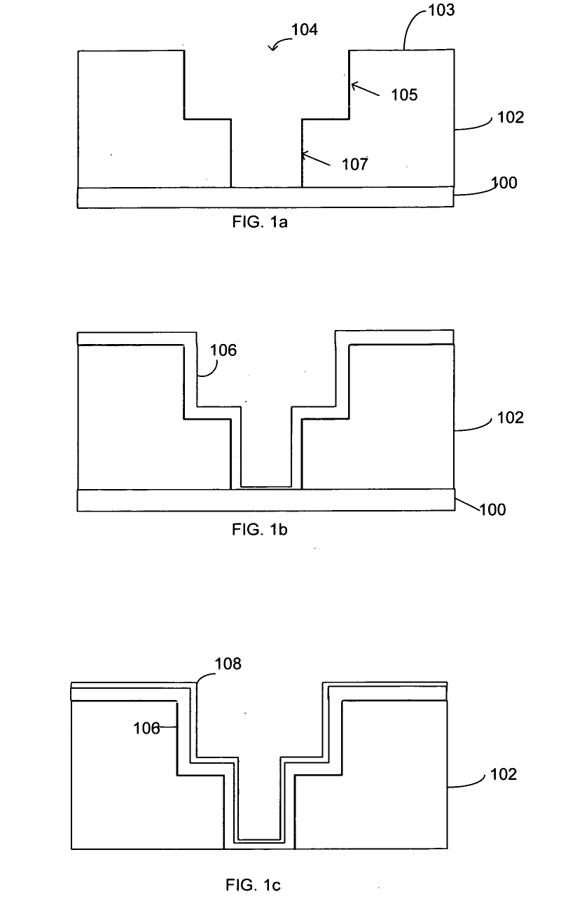

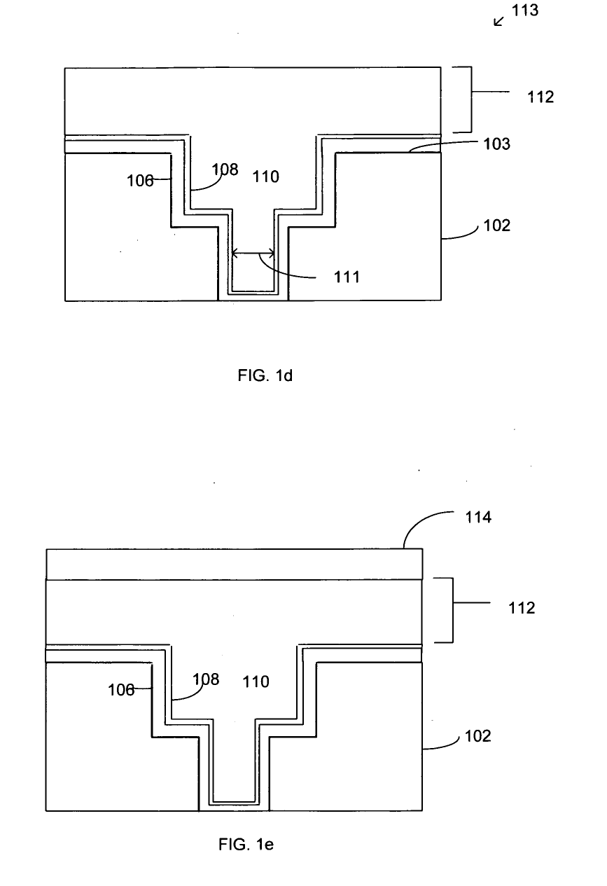

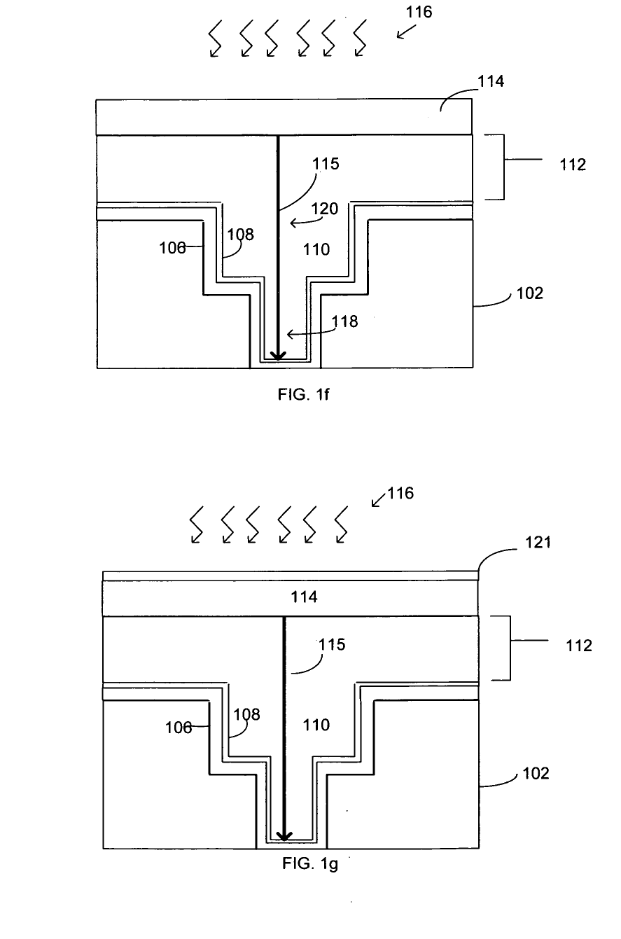

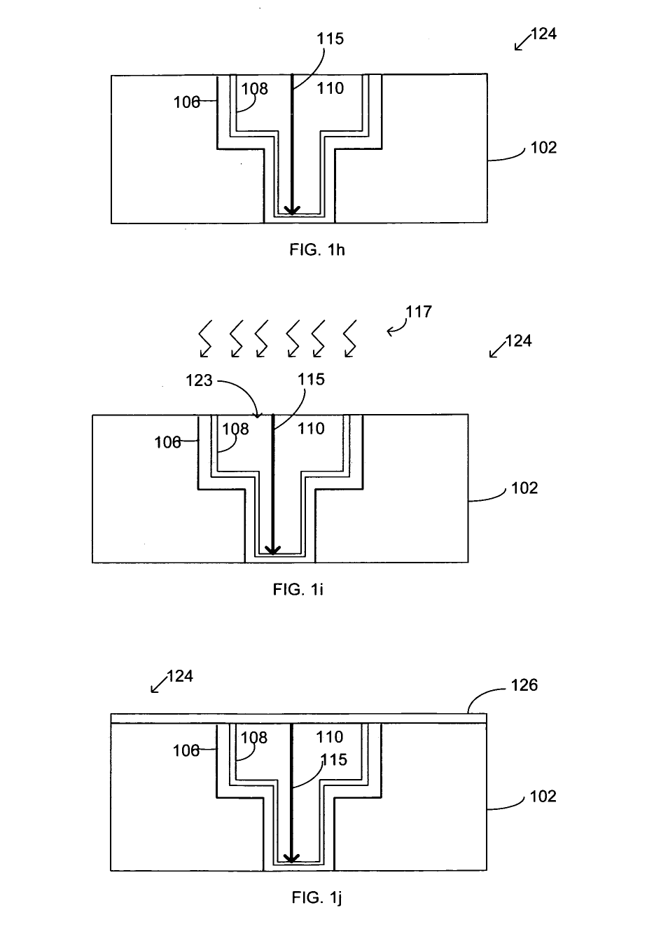

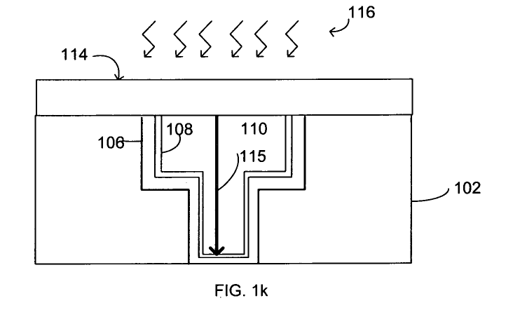

In an embodiment of the present invention, a dielectric layer 102 may be disposed on a substrate 100 (FIG. 1a). The substrate 100 may comprise materials such as silicon, silicon-on insulator, germanium, indium antimonide, lead telluride, indium arsenide, indium phosphide, gallium arsenide, gallium antimonide carbon nanotubes, any type of nanotube structure, organic semiconductor materials, and combinations thereof. Although several examples of materials from which the substrate 100 may be formed are described here, any material that may serve as a foundation upon which a microelectronic device may be built falls within the spirit and scope of the present invention.

The dielectric layer 102 may comprise a variety of materials, thicknesses or multiple layers of material. By way of illustration and not limitation, the dielectric layer 102 may include silicon dioxide, organic materials or inorganic materials. In one embodiment, the dielectric layer 102 may comprise a low k dielectric material, and may comprise a dielectric constant below about 3.0. The dielectric layer 102 may comprise a top surface 103. The dielectric layer 102 may comprise at least one opening 104. In one embodiment, the at least one opening 104 may comprise a trench portion 105, and a via portion 107, which may comprise a portion of a damascene structure which may be used to connect conductive layers to each other within a microelectronic device, for example, as is known by those skilled in the art.

In one embodiment, a barrier layer 106 may be deposited onto/within the at least one opening 104 (FIG. 1b) and may line the at least one opening 104. Those skilled in the art will appreciate that the barrier layer 106 may be formed from a variety of materials, thicknesses or multiple layers of material. In one embodiment, the barrier layer 106 can include any one of the following materials: tantalum, tungsten, titanium, ruthenium, cobalt and their alloys with light elements such as, but not limited to nitrogen, silicon and carbon, and combinations thereof. Although a few examples of materials that may be used to form the barrier layer 106 are described here, that layer may be made from other materials that serve to prevent the diffusion of a conductive material across the barrier layer 106. In one embodiment, the barrier layer 106 can range from a monolayer to about 500 angstroms. The barrier layer 106 material may also be used as a seed layer for subsequent interconnect structure formation in some cases. The barrier layer 106 may also be used to dope such an interconnect structure material and may provide electromigration resistance.

In one embodiment, a seed layer 108 may be formed on the barrier layer 106 (FIG. 1c). In one embodiment, the seed layer 108 may be formed utilizing various deposition techniques, such as, but not limited to, chemical vapor deposition (CVD), physical vapor deposition (PVD) and/or an atomic layer deposition (ALD) processes. The seed layer 108 may comprise any type of material, depending upon the particular application. In other embodiments, the seed layer 108 may be omitted. In one embodiment, the seed layer 108 may serve to activate a surface, such as the surface of the barrier layer 106, in order to prepare for or enable deposition of another layer, such as a copper plated layer, for example. In one embodiment, the seed layer 108 may comprise at least one of ruthenium, tantalum, titanium, titanium nitride, tantalum nitride, copper, copper alloys and combinations thereof.

A conductive structure 110 may be formed on the seed layer 108/barrier layer 106 (FIG. 1d). In one embodiment, the conductive structure 110 may be formed by at least one of an electroless deposition process and an electroplating process, as are known in the art. In one embodiment, the conductive structure 110 may comprise at least one of copper, aluminum, nickel, tungsten, nickel silicide, cobalt, and molybdenum and may comprise a conductive trace within a microelectronic device. The conductive structure 110 may comprise an overburden region 112. The overburden region 112 may comprise a portion of the conductive structure 110 that may be disposed above the top surface 103 of the dielectric layer 102. In one embodiment, the conductive structure 110 may comprise a width 111 of less than about 100 nm, and may comprise a width 111 of less than 32 nm in some cases. In one embodiment, the interconnect structure 113 of FIG. 1d may comprise a portion of a damascene interconnect structure.

A doping material 114 may be formed on top of the overburden region 112 of the conductive structure 110, wherein the doping material may comprise an alloy or a pure metal (FIG. 1e) in some cases. In one embodiment, the doping material 114 may be formed by the sputtering of copper alloyed with common metals such as but not limited to aluminum, manganese, tin, magnesium, copper, palladium, indium, zirconium, and zinc onto the overburden region 112. In another embodiment, the doping material 114 may be formed by the sputtering of pure metals or the sputtering of non copper alloys such as aluminum, manganese, tin, magnesium, copper, palladium, indium, zirconium, and zinc onto the overburden region 112.

The doping material 114 may also be formed on the overburden region 112 by the evaporation of alloyed copper, pure metal or non copper alloyed materials. The doping material 114 may also be formed on the overburden region 112 by the electroplating of alloyed Copper or pure metals using commonly known electroplating chemistries, and the electroless plating of alloyed copper and or pure metals using commonly known electroless chemistries.

A portion of the doping material 114 may be diffused 116 into a portion of the conductive structure 110 (FIG. 1f), utilizing any suitable diffusion technique, such as but not limited to rapid thermal anneal and furnace anneal processes. In one embodiment, the portion of the doping material 114 may be diffused 116 into the portion of the conductive structure 110 by performing at least one anneal of a portion of the doping material 114 at a temperature of between about 100 and 500 degrees Celsius for 1 to 24 hours in some cases. In one embodiment, the portion of the doping material 114 that diffuses into the conductive structure 110 may form an alloy with the conductive structure 110. In one embodiment, the portion of the doping material 114 that diffuses into the conductive structure 110 may serve to dope the conductive structure 110 with the doping material 114. In other words, the doping material 114 may comprise a dopant material for the conductive structure 110. In some embodiments at least one of the seed layer 108 and the barrier layer 106 may further contribute to the doping of the conductive structure 110, thus allowing for the tuning of the doping percentage and the location of the dopant within the interconnect material 110, according to the particular application.

The alloy formation may improve the electromigration resistance of the conductive structure 110, especially when the conductive structure 110 comprises a relatively narrow interconnect structure, such as a conductive copper line comprising less than about 32 nm. In one embodiment, the seed layer 108 may comprise non copper based materials that cannot typically form alloys with materials that may reduce electromigration, such as aluminum. For example, ruthenium can be used as the seed layer while using aluminum in the doping material to reduce electromigration failures of the conductive structure. In some embodiments, the doping material that is diffused into the conductive structure may protect the conductive structure from at least one of corrosion, barrier failure, electromigration failure, adhesion failure and oxidation failure.

In one embodiment, a range of the concentration of the doping of the conductive structure 110 may comprise a percentage from about 0.1 to about 10 percent of the doping material in the conductive structure, and a resistivity of the conductive structure after the doping may comprise less than about 6 micro-ohm centimeters. It will be understood that the particular doping concentrations and resistivities of the conductive structure 110 will depend upon the particular application. In one embodiment, the doping material that is diffused into the conductive structure may comprise a substantially uniform copper alloy throughout the conductive structure 110.

In one embodiment, a concentration gradient 115 of the dopant in the conductive structure 110 may comprise a higher percentage of the dopant at a top portion 120 of the conductive structure 110, and a lower percent of the dopant at a bottom portion 118 of the conductive structure 110. For example, the concentration gradient 115 of the dopant in the conductive structure 110 may vary from about 10 percent of the dopant at the top portion 120 of the conductive structure 110 to about 1 percent of the dopant at the bottom portion 118 of the conductive structure 110.

In this manner, doping of the conductive structure 110 by the doping material may be performed post bulk conductive structure formation, such as post copper interconnect formation, for example. In an embodiment, thermal diffusion of the dopant of the doping material 114 through the overburden region 112 of the conductive structure 110 serves to drive the alloyed conductive material of the overburden region 112 of the conductive structure 110 into the non-overburden region (that region of the conductive structure 110 below the plane of the top surface 103 of the dielectric layer 102) of the conductive structure 110.

The amount of dopant that may be diffused into the conductive structure 110 may be controlled by anneal, anneal time, number of anneals performed and the overburden 112 thickness, for example. The process parameters of the diffusion process 116 can be tailored for optimization, and in some cases the temperature of the diffusion process 116 can be under about 500 degrees, and as low as about 100 degrees. In some embodiments, the doping of the conductive structure 110 may be compatible with direct plating schemes that rely on little to no copper or copper alloy seed layers.

Diffusion profiles may be optimized to give the maximum dopant at the top of the conductive structure 110 post traditional chemical mechanical processing (CMP) processing. Traditional doping of conductive structures, such as copper lines, occurs by doping a copper seed layer prior to bulk copper formation. Unfortunately this strategy may falter in sub 100 nm lines due to the limited amount of alloy that can be delivered in scaled copper seeds layers. Thermal diffusion of the overburden dopant into the conductive structure will serve to alleviate this alloy problem.

The overburden doping of the various embodiments will leave a very characteristic dopant profile in the conductive structure 110. Due to the top down nature of the doping process, overburden doping may exhibit little to no alloy at the bottom of the conductive structure, as compared with prior art alloy seed doping schemes, which may exhibit clumps of dopant at top and bottom and edge portions of the conductive structure. Additionally, prior art alloyed copper seed layers may lose effectiveness in sub 100 nm interconnects due to lack of sidewall coverage, for example. Gap-fill at 32 nm and beyond may be challenging due to difficulties filling narrow trenches with alloyed seed layers, thus the methods of the present invention allows for thinner, more pure seed layers to be utilized. The doping process of the various embodiments may avoid gap-fill void issues commonly associated with high alloy concentration seed layers.

In prior art interconnect structures alloy levels may be too high in the sputtered seed layers that are deposited prior to bulk copper deposition. The alloy can then oxidize and cause copper voiding during formation. These voids may coalesce and result into electromigration failures. These electromigration failures become exacerbated in sub 100 nm interconnect structures since the amount of alloy decreases substantially in smaller lines and the alloy amount in the copper seed cannot be increased due to the voiding issues which may develop when the copper seed becomes too highly doped. The embodiments of the present invention allow for the extension of copper interconnects for sub 32 nm technologies since the doping of interconnect lines can be done by the doping material.

In an embodiment, an optional capping structure 121 can be formed on top of the overburden region 112 prior to the diffusion process 116 (FIG. 1g) in order to maximize/optimize the dopant diffusion profile and inhibit surface agglomeration of the dopant. In an embodiment, the capping structure 121 may comprise a dielectric material for example, and other such capping materials according to the particular application. Removal of the overburden region 112 and the portion of the seed layer 108 and the barrier layer 108, 106 disposed on top of the top surface 103 of the dielectric layer 102 may be performed using CMP technologies, for example (FIG. 1h) to form the interconnect structure 124. In an embodiment, the 124 interconnect structure that may be alternatively formed by a direct patterning technique. In yet another embodiment, the doping material may be formed directly on the conductive structure 110 after the overburden region 112 is removed, and then a portion of the doping material may be diffused into a portion of the conductive structure, as described above herein (FIG. 1k).

In an embodiment, post removal plasma and/or chemical treatments and further annealing 117 may be performed on the conductive structure 110 of the interconnect structure 124 in order to further optimize the concentration gradient 115 of the doping elements on the surface 123 of the conductive structure 110 and within the bulk region of the conductive structure 110 (referring back to FIG. 1i). For example, plasma hydrogen treatments may be performed to achieve desired diffusion characteristics for the particular application. The interconnect structure 124 may be optionally capped with a layer 126, such as but not limited to an etch stop and/or an interlayer dielectric (ILD) (FIG. 1j). In an embodiment, the interconnect structure 124 may comprise a portion of a transistor structure 124. In an embodiment, the interconnect structure 124 may comprise a copper interconnect, may comprise a transistor gate width of less than about 32 nm.

A benefit of the overburden doping methods of the various embodiments of the present invention is that the mean time to electromigration failure may continuously increases with the amount of alloy dopant added to the conductive structure 124. One of the reasons the mean time to electromigration failure falls off at higher alloy seed concentrations for prior art interconnect structures is because the higher alloy concentrations may change the ability of the fill chemistry to work effectively when filling narrow gaps. In some embodiments, a mean time to failure for electromigration for the transistor may comprise a linear function with resistivity of the conductive structure, wherein in some cases a mean time to failure for electromigration for the conductive structure may increase with the resistivity of the conductive structure. Additionally, the doping material that is diffused into the conductive structure may serve as a barrier and/or an electromigration protecting distribution.

As described above, the methods of the present invention enable the use of higher current densities to be used in the design of conductive interconnects for advanced IC technologies and the continuation of using traditional bulk copper deposition technologies. Without this invention, sub 100 nm interconnects may be severely limited due to electromigration failures. The various embodiments allow for independent metallurgical choice and integration of electromigration enabling solutions.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that the fabrication of a conductive layers within a substrate, such as a silicon substrate, to manufacture a microelectronic device is well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
forming a doping material on top of a conductive structure; and
diffusing a portion of the doping material into a portion of the conductive structure.

2. The method of claim 1 further comprising wherein the doping material is formed by at least one of a sputtering, evaporation, electroless plating and an electroplating method.

3. The method of claim 1 further comprising wherein the doping material comprises at least one of a copper alloy, a non-copper alloy and a substantially pure material.

4. The method of claim 3 wherein the copper alloy comprises at least two of copper, aluminum, manganese, tin, cobalt, magnesium, palladium, indium, zirconium and zinc, and wherein the substantially pure material comprises one of copper, aluminum, manganese, tin, cobalt, magnesium, palladium, indium, zirconium and zinc, and wherein the non-copper alloy comprises at least two of aluminum, manganese, tin, cobalt, magnesium, palladium, indium, zirconium and zinc.

5. The method of claim 1 wherein diffusing a portion of the doping material into a portion of the conductive structure comprises performing at least one anneal of the doping material at a temperature of between about 100 and 500 degrees Celsius.

6. The method of claim 1 further comprising wherein the doping material comprises a dopant, and wherein the portion of the doping material that is diffused into the conductive structure comprises a higher concentration of the dopant in a top portion of the conductive structure than in a bottom portion of the conductive structure.

7. The method of claim 1 further comprising wherein the doping material that is diffused into the conductive structure comprises a substantially uniform copper alloy throughout the conductive structure.

8. The method of claim 1 further comprising wherein the doping material that is diffused into the conductive structure protects the conductive structure from at least one of corrosion, barrier failure, electromigration failure adhesion failure and oxidation failure, and wherein the conductive structure comprises a portion of a damascene structure, wherein the conductive structure is formed on a seed layer disposed on a barrier layer, wherein at least one of the barrier layer and the seed layer further dopes the interconnect structure.

9. The method of claim 1 further comprising forming a capping structure on the conductive structure prior to diffusing the portion of the doping material.

10. A method comprising:
forming a barrier layer within at least one opening of a dielectric material;
forming a conductive structure on the barrier layer, wherein the conductive structure comprises an opening filled with metal and an overburden region;
removing the overburden region from the conductive structure;
forming a doping material on the conductive structure; and
diffusing a portion of the doping material into a portion of the conductive structure.

11. The method of claim 10 further comprising wherein the opening comprises a portion of a damascene structure, and wherein a seed layer is formed on the barrier layer, wherein at least one of the barrier layer and the seed layer further dopes the conductive structure.

12. The method of claim 10 further comprising wherein the doping material comprises at least one of a copper alloy, a non-copper alloy and a substantially pure material, and wherein the conductive structure may comprise a portion of an interconnect structure that may be formed by a direct patterning technique.

13. The method of claim 10 wherein the doping material comprises a dopant, and wherein the portion of the doping material that is diffused into the conductive structure comprises a higher concentration of the dopant in a top portion of the conductive structure than in a bottom portion of the conductive structure, and wherein a concentration gradient of the dopant in the conductive structure comprises from about 10 percent of the dopant at the top portion to about 1 percent of the dopant at the bottom portion of the conductive structure.

14. An interconnect structure comprising:
a conductive structure disposed on a barrier layer; and
a dopant disposed within the conductive structure, wherein the conductive structure comprises a higher concentration of the dopant in a top portion of the conductive structure than in a bottom portion of the conductive structure.

15. The structure of claim 14 wherein the dopant comprises at least one of aluminum, manganese, tin, cobalt, magnesium, palladium, indium, zirconium and zinc, and wherein the conductive structure comprises copper.

16. The structure of claim 14 wherein a concentration of the dopant comprises from about 10 percent of the dopant in the top portion of the conductive structure to about 1 percent of the dopant in the bottom portion of the conductive structure.

17. The structure of claim 14 wherein the interconnect structure comprises a portion of a transistor structure, and wherein a mean time to failure for electromigration for the conductive structure increases with the resistivity of the conductive structure.

18. The structure of claim 14 wherein the conductive structure comprises at least one of copper, aluminum, nickel, tungsten, nickel silicide, cobalt, and molybdenum.

19. The structure of claim 14 further comprising wherein the dopant is capable of forming an alloy with the conductive structure.
